(19) United States
(12) Patent Application Publication
(10) Pub. No.: US 2026/0135549 A1
(43) Pub. Date: May 14, 2026

(54) CIRCUIT ARRANGEMENT FOR CONTROLLING A LOAD

(71) Applicant: Inventronics GmbH, Garching b. München (DE)

(72) Inventors: Joachim Mühlschlegel, Gröbenzell (DE); Francesco Angelin, Mogliano Veneto (IT)

(21) Appl. No.: 19/119,613

(22) PCT Filed: Oct. 27, 2023
(86) PCT No.: PCT/EP2023/080111

§ 371 Date: Apr. 9, 2025

(30) Foreign Application Priority Data
Oct. 27, 2022 (DE) 10 2022 211 425.6

(51) Int. Cl. H03K 17/041

(52) U.S. Cl. CPC H03K 17/04106

(57) ABSTRACT

A circuit arrangement (1) serves for driving a load, in particular a gate of a power transistor (M1). The circuit arrangement comprises a first input terminal (IN1) for inputting a voltage signal (Vin) in order to switch between states of the load, a first and a second output terminal (OUT1, OUT2) for outputting a first and second output voltage (Vout1, Vout2), a PNP bipolar transistor (Q1) and an NPN bipolar transistor (Q2), a first signal path (SP1) which is connected between the first input terminal and the base of the PNP bipolar transistor, and a second signal path (SP2) which is connected between the first input terminal and the base of the NPN bipolar transistor. The emitter of the first transistor is connected to a supply terminal (VCC). The collector of the first transistor is connected to the first output terminal. The emitter of the second transistor is connected to a ground terminal (GND). The collector of the second transistor is connected to the second output terminal. The first signal path contains a level shifter (Q6, R6) which is configured to shift the voltage signal into a level range suitable for switching the first transistor. The first signal path furthermore contains a first capacitor (C3), one end of which is connected upstream of the level shifter in the signal flow direction to the first signal path and the other end of which is connected downstream of the level shifter in the signal flow direction to the first signal path.

### TECHNICAL FIELD

The invention relates to a circuit arrangement, or switching assembly, for driving or controlling a load. This load may be, for example, a gate of a field-effect transistor or of a MOSFET or of an IGBT. However, other loads which are intended to be operated are also conceivable. In particular, the invention relates to specific amplifier circuit arrangements for controlling a gate, for example, of power MOSFETs, so-called gate drivers, as are used, inter alia, in switched-mode power supplies or in ballasts (for example for operating LED devices), in step-up converters of power factor correction filters (PFC) or flyback converters or in buck converters, etc. In this case, in particular a configuration with common ground is taken into consideration, which means that the input voltage signal is essentially related to the same ground potential (“ground”) as is also the relevant source terminal of the driven MOSFET. The expression “essentially to the same ground potential” means in this case that, for example, a low-resistance measuring resistor may be connected between the source terminal and ground.

### TECHNICAL BACKGROUND

It is known that such types of amplifier circuits drive the driven component, in particular the corresponding MOSFET, merely applying a gate signal with either a low level (“low-level”) or a high level (“high-level”), in order to achieve a transition between the switched-on state (“on-state”) and the switched-off state (“off-state”) which is as short in time as possible. Such an amplifier circuit consequently operates in a highly non-linear manner. As a rule, a certain hysteresis occurs at these transitions. Since, moreover, the gate of the MOSFET essentially also contains a capacitive load, relatively high currents flow here solely during the voltage transitions when switching between the switching states of the MOSFET.

A function of the amplifier circuits or of such gate drivers is, furthermore, to be driven by a control unit or by a microcontroller (μC) with a moderate current and voltage swing, in order then to serve both as a buffer and as an amplifier with a larger output swing for current and voltage between the microcontroller and the power MOSFET.

In particular, the gate drivers considered here are configured to provide up to a few hundred milliamperes at the gate of the driven MOSFET for the charging and discharging of the gate. The output power of a ballast with this type of gate drivers can range, for example, from 10 W to 1000 W.

It is known in this context to add additional current amplifiers in the form of standard components to the gate driver, such as, for instance, a complementary emitter follower, in order to even further increase the output current of the gate driver.

It is widespread to design such gate drivers in the form of integrated circuits. As a result, the components are very compact and may at the same time supply relatively high current pulses for switching the driven MOSFET on and off. On the other hand, such gate drivers designed as integrated components or chips are usually quite expensive and, depending on the brand and model, unique, so that they cannot be replaced easily in the event of unavailability. In addition, a corresponding potential peak current is normally at least in the ampere range. Such dimensions of the output current in this case not only increase the bill-of-material, but may also be excessively large from a technical point of view and even lead to problems in some applications.

As a result, alternative solutions with discrete components may still be considered to be expedient, specifically if a limited output current proves to be sufficient, the available space upon the printed circuit board is not dimensioned too narrowly and, in addition, an inexpensive, easily exchangeable solution is required.

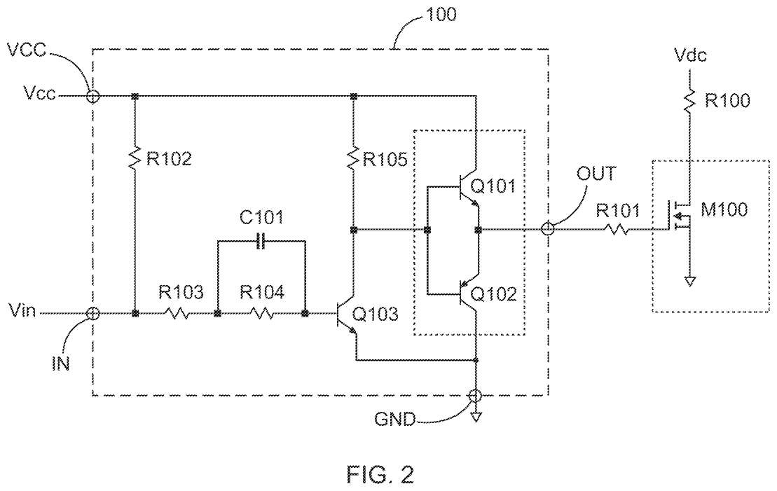

A known gate driver circuit with discrete electronic components is illustrated in FIG. 2. The circuit arrangement 100 has a supply terminal VCC, a ground terminal GND, an input terminal IN and an output terminal OUT. The gate driver circuit shown serves for driving the gate of a MOSFET M100, the gate of which is connected via a resistor R101 to the output terminal OUT of the circuit arrangement 100. An external load is connected to the drain of the MOSFET M100. This external load may be, for example, an inductance or a transformer or a coupling capacitance or a resistor or a corresponding circuit. The source is connected to the common ground. The external load assumed in FIG. 2 is, by way of example, a resistor R100, which is connected to a DC voltage Vdc.

The ground terminal GND of the circuit arrangement 100 is likewise connected to ground. A supply voltage Vcc is applied between the supply terminal VCC and the ground terminal. A voltage signal Vin, which is supplied, for example, by a microcontroller and is used to switch the MOSFET M100 from a switched-on state (“on-state”) to a switched-off state (“off-state”) and vice versa, is applied to the input terminal IN.

In the circuit arrangement 100, the input terminal IN is connected via a resistor R102 to the supply terminal VCC and via a series circuit comprising a resistor R103 and a parallel circuit comprising a resistor R104 and a capacitor C101 to a base of an NPN bipolar transistor Q103. The collector of the transistor Q103 is connected via a resistor R105 to the supply terminal VCC, and the emitter is connected to the ground terminal GND.

The circuit arrangement 100 contains a complementary output stage comprising an NPN bipolar transistor Q101 and a PNP bipolar transistor 102. The bases of the two transistors Q101, Q102 are connected to one another and to the collector of the transistor Q103. The emitters of the two transistors Q101, Q102 are connected to one another and to the output terminal OUT. The collector of the transistor Q101 is connected to the supply terminal VCC. The collector of the transistor Q102 is connected to the ground terminal GND.

The principle of this solution consequently consists in allowing a common inverting amplifier (NPN bipolar transistor in common emitter circuit), which at the same time serves as a level shifter, to be followed by two non-inverting emitter followers composed of mutually complementary transistors, in order to increase the output voltage level and the output current. This solution is not only rather simple but also inexpensive.

However, in this interconnection, in order to achieve the off-state of the MOSFET M100, the transistor Q103 has to be switched on, and a current flows via the resistor R105 and the transistor Q103. If, for example, the underlying switched-mode power supply is now in a standby mode since, although it is supplied with power on the one hand, the external load, such as, for example, a lighting means, etc., is nevertheless not activated, a permanent quiescent current flows through the resistor R105 and the transistor Q103 in this state. For example, at a typical supply voltage of Vcc=12 V and a resistance value of R105=3.3 kΩ, a quiescent current of approximately 3 mA results. A customary microcontroller operated at 3.3 V likewise has a quiescent current of approximately 3 mA in standby mode. The quiescent current is therefore approximately doubled by the circuit arrangement 100 described above. This additional quiescent current, which cannot be used in any way, should be avoided.

Moreover, the circuit arrangement is inverting without the possibility of keeping the field-effect transistor M100 in the OFF state if, for example, the circuit connected to the input terminal or the microcontroller is no longer ready for operation. There is no possibility of inputting an enable signal which enables or blocks the operation of the driver.

In addition, a voltage drop per se takes place both at the high-side NPN transistor Q101 and at the low-side PNP transistor Q102 on account of their arrangement as an emitter follower. In each case at least approximately 0.6 V (i.e. the base-emitter voltage) is missing up to the voltages at the two terminals VCC and GND. The voltage swing at the gate of the field-effect transistor M100 is consequently also restricted by the corresponding voltage drop at the base-emitter junction. As a result, an actually desired rail-to-rail capability that the swing of the output voltage corresponds virtually to the voltage between VCC and GND is restricted.

Mention should also be made of the possibility, which unfortunately does not exist here, of dividing the output at the control connection point towards the gate into two different terminals, one of which could serve, for example, as a current source and the other as a current sink. Decoupling of the two emitters would lead, in the circuit arrangement shown, to reverse biasing of the base-emitter junction of a respective currently non-conducting bipolar transistor during switching. This would in turn damage the bipolar transistors.

It is therefore an object of the present invention to provide a circuit arrangement, or switching assembly, for driving a load, in particular a gate of a transistor, in which the quiescent current is reduced and switching properties such as, for example, switching speed and rail-to-rail capability are improved.

The object is achieved by a circuit arrangement, or switching assembly, according to claim 1. Embodiments of the invention are each specified in the dependent claims.

The circuit arrangement according to the invention serves for driving or controlling a load, in particular a gate of a power transistor. The circuit arrangement comprises a ground terminal and a supply terminal for applying a supply voltage, a first input terminal for inputting a voltage signal in order to switch between states of the field-effect transistor, a first and a second output terminal or a common output terminal for outputting a first and second output voltage or a common output voltage, for driving the gate of the field-effect transistor, a first transistor and a second transistor, wherein the first transistor is formed as a PNP bipolar transistor and the second transistor is formed as an NPN bipolar transistor or as an N-channel field-effect transistor or wherein the first transistor is formed as an NPN bipolar transistor and the second transistor is formed as a PNP bipolar transistor or as a P-channel field-effect transistor, a first signal path which is connected directly or via a first resistor between the first input terminal and the base or the gate of the first transistor, and a second signal path which is connected directly or via the first resistor between the first input terminal and the base or the gate of the second transistor.

The emitter of the first transistor is connected directly or via a supply resistor to the supply terminal. The collector of the first transistor is connected directly or via a first internal output resistor to the first output terminal or to the common output terminal. The emitter or the source of the second transistor is connected directly or via an emitter resistor to the ground terminal. The collector or the drain of the second transistor is connected directly or via a second internal output resistor to the second output terminal or to the common output terminal. The first signal path contains a level shifter which is configured to shift the voltage signal into a level range suitable for switching the first transistor. The first signal path furthermore contains a first capacitor, one end of which is connected directly or via the first resistor (R2) to the first input terminal and the other end of which is connected directly or via a second resistor to the base of the first transistor.

In such a circuit arrangement, the voltage swing of the output voltage can be increased, for example, by the interconnection of the first and second transistors, as a result of which the rail-to-rail capability is improved. Furthermore, a low-impedance AC current path can be provided by the first capacitor, which AC current path does not allow a quiescent current to pass through, but accelerates the switching on and off of the first transistor in that it conducts a pulse current to the base of the first transistor in a virtually delay-free manner in the event of a level change of the input signal.

In an advantageous embodiment, the circuit arrangement is dimensioned such that, in the event of a level change of the voltage signal, a pulse current from the first input terminal is conducted via the first capacitor to the base of the first transistor so quickly that the first transistor is already switched off when the second transistor is completely switched on, and vice versa. As a result, an undesired transverse current between the first transistor and the second transistor can be prevented, for example.

In an advantageous embodiment, the second signal path contains a parallel circuit comprising a second capacitor and a third resistor, which parallel circuit is connected in series with the base or the gate of the second transistor. As a result, a low-impedance AC current path can be provided, for example, which AC current path accelerates the switching on and off of the second transistor.

In an advantageous embodiment, a ratio between a capacitance value of the first capacitor and a capacitance value of the second capacitor lies in a range from 0.25 to 4, preferably in a range from 0.5 to 2, further preferably in a range from 0.75 to 1.5. As a result, the signal transmission speeds of the first and second signal paths can be suitably adapted to one another, for example.

In an advantageous embodiment, a time constant, which results as a product of a resistance value of the third resistor and a capacitance value of the second capacitor, lies in a range from 100 ns to 3000 ns, preferably in a range from 200 ns to 1500 ns. As a result, a suitable transfer function of the second signal path can be realized, for example.

In an advantageous embodiment, the level shifter contains a third transistor which is formed as a bipolar transistor of the same polarity as the second transistor and is connected in a common base circuit. Preferably, the level shifter furthermore contains a first resistor which is connected in series with the emitter of the third transistor. As a result, a level shifter with a low standby quiescent current can be realized, for example.

In an advantageous embodiment, the circuit arrangement furthermore contains a second input terminal for inputting an external voltage or an enable signal, wherein the second input terminal is connected directly via a voltage divider to the base of the third transistor, wherein the second input terminal is preferably designed for use as an enable input for blocking or enabling the operation of the first transistor. As a result, a base voltage of the third transistor can be easily adapted, for example, in the event of a change in a voltage swing of the input signal, and in the power-up, the first transistor can be prevented from switching on by applying a signal with a low level independently of the current level of the voltage signal.

In an advantageous embodiment, the second input terminal is connected via a first voltage divider resistor to the base of the third transistor and the base of the third transistor is connected via a second voltage divider resistor to the ground terminal, wherein preferably a ratio between the resistance values of the first voltage divider resistor and of the second voltage divider resistor is selected in such a way that the voltage potential present at the base of the third transistor lies in a range from

$$V IN max - 1.5 * ( V IN max + V IN min ) / 2 to V IN max or from 0.9 V to V IN max ,$$

or further preferably lies in a range from

$$V IN max - 0.6 * ( V IN max + V IN min ) / 2 to V IN max - 0.3 * ( V IN max + V IN min ) / 2 ,$$

wherein VINmax corresponds to a high level and VINmin corresponds to a low level of the voltage signal. As a result, the base voltage of the third transistor can be easily set to a value suitable for the switching operation, for example.

In an advantageous embodiment, the first and the second signal path are configured such that, when a voltage signal having a low level is input at the first input terminal, an output voltage at the first output terminal or the common output terminal is substantially equal to the supply voltage, whereas, when a voltage signal having a high level is input at the first input terminal, an output voltage at the first output terminal or the common output terminal is substantially equal to the ground potential. As a result, an inverting gate driver can be realized, for example.

In an advantageous embodiment, the circuit arrangement furthermore contains a third input terminal for inputting a switch-off voltage signal, wherein the first signal path and the second signal path are connected via the first resistor to the first input terminal and the third input terminal is connected to a node which is common to the first and the second signal path but is not the first input terminal. As a result, the load can be put into the OFF-state independently of the voltage present at the first input terminal, for example in the event of a fault such as, for example, an overtemperature.

In an advantageous embodiment, the circuit arrangement contains a first diode which is connected on the anode side to the emitter or the source and on the cathode side to the collector or the drain of the second transistor. As a result, a polarity reversal of the output voltage of the second transistor can be prevented, for example.

In an advantageous embodiment, the circuit arrangement contains a second diode which is connected on the anode side to the collector or the drain and on the cathode side to the base or the gate of the first transistor, and/or a third diode which is connected on the anode side to the base or the gate and on the cathode side to the collector or the drain of the second transistor. As a result, saturation of the respective transistor can be prevented, for example.

In an advantageous embodiment, the second transistor is formed by a complementary Darlington circuit comprising a fourth transistor of the polarity of the second transistor and a fifth transistor of the polarity of the first transistor. As a result, a current gain of the second transistor can be increased, for example.

In an advantageous embodiment, the circuit arrangement furthermore contains a power transistor having a gate, wherein the gate of the power transistor is connected directly or via a first external output resistor to the first output terminal and directly or via a second external resistor to the second output terminal, or wherein the gate of the power transistor is connected directly or via an external output resistor to the common output terminal. As a result, a complete circuit arrangement for driving a load can be realized, for example.

In an advantageous embodiment, a first total sum of the resistances between the collector or the drain of the first transistor and the gate of the power transistor is greater than a second total sum of the resistances between the collector or the drain of the second transistor and the gate of the power transistor, preferably greater by at least the factor 2, further preferably greater by at least the factor 4. As a result, the functions as a current source and as a current sink can be suitably set, for example.

Further features and expedients of the invention emerge from the description of an exemplary embodiment with reference to the appended drawings.

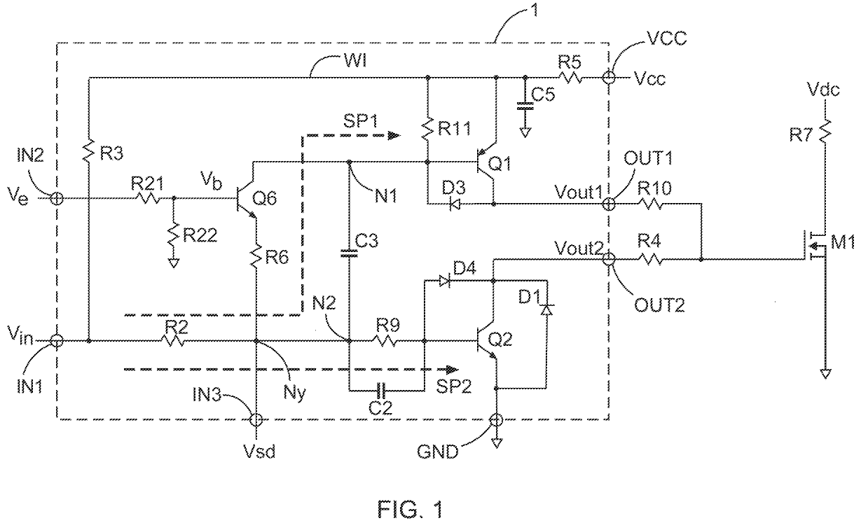

FIG. 1 shows a circuit diagram of a circuit arrangement for driving a gate of a field-effect transistor according to an embodiment of the present invention.

FIG. 2 shows a circuit diagram of a known circuit arrangement for driving a gate of a field-effect transistor.

An embodiment of the present invention is described below with regard to various modifications and with reference to the appended drawings.

FIG. 1 shows a circuit diagram of a circuit arrangement 1, or switching assembly, for driving a gate of a field-effect transistor according to the embodiment. It contains a supply terminal VCC, a ground terminal GND, three input terminals IN1, IN2, IN3 and two output terminals OUT1, OUT2.

The circuit arrangement 1 serves for driving a MOSFET M1, which is an n-channel MOSFET of the enhancement mode type. A MOSFET of this type is self-blocking, which means that it blocks when a voltage present between gate and source is 0 V, and only conducts when this voltage exceeds a positive threshold voltage.

The MOSFET M1 serves for driving an external load which, as described at the outset, may contain, for example, an inductance or a transformer or a coupling capacitance or a resistor or a corresponding circuit. The external load is illustrated schematically in FIG. 1 as a resistor R7, which is connected to a DC voltage Vdc.

The gate of the MOSFET M1 is connected via a resistor R10 to the output terminal OUT1 and via a resistor R4 to the output terminal OUT2. The source of the MOSFET M1 is connected to the common ground.

The ground terminal GND of the circuit arrangement 1 is likewise connected to ground. The supply terminal VCC is connected to ground via a series circuit comprising a relatively low-resistance resistor R5 and a capacitor C5. The connection point between the resistor R5 and the capacitor C5 is connected to an internal supply line WI.

As output transistors, the circuit arrangement 1 contains a PNP bipolar transistor Q1 and an NPN bipolar transistor Q2. The emitter of the transistor Q1 is connected to the internal supply line WI. The collector of the transistor Q1 is connected to the output terminal OUT1. The emitter of the transistor Q2 is connected to the ground terminal GND. The collector of the transistor Q2 is connected to the output terminal OUT2.

A diode D1 is connected on the anode side to the emitter and on the cathode side to the collector of the transistor Q2. A diode D3 is connected on the anode side to the collector and on the cathode side to the base of the transistor Q1. A diode D4 is connected on the anode side to the base and on the cathode side to the collector of the transistor Q2.

The base of the transistor Q1 is connected via a resistor R11 to the internal supply line WI. The input terminal IN1 is connected via a resistor R3 to the internal supply line WI.

The input terminal IN1 is connected via a first signal path SP1 to the base of the first transistor Q1 and via a second signal path SP2 to the base of the second transistor Q2. The signal paths are illustrated in the figure by dashed lines. The arrow tips indicate the signal flow directions which extend in each case from the input terminal IN1 to the first or second transistor Q1, Q2.

The two signal paths contain a common partial path which is formed by a resistor R2 which is connected between the input terminal IN1 and a branching node Ny. The third input terminal IN3 is connected to the branching node Ny.

The first signal path SP1 contains, in the signal flow direction downstream of the branching node Ny, a level shifter which is configured to shift the voltage signal Vin into a level range suitable for switching the first transistor Q1, that is to say into a level range in the vicinity of the supply voltage Vcc.

The level shifter contains an NPN bipolar transistor Q6 which is arranged in a common base circuit. The emitter of the transistor Q6 is connected via an emitter resistor R6 to the branching node Ny, and the collector is connected to the base of the transistor Q1. The base of the transistor Q6 is connected via a resistor R21 to the input terminal IN2 and via a resistor R22 to ground.

The second signal path SP1 furthermore contains a parallel circuit comprising a resistor R9 and a capacitor C2, which parallel circuit is connected between the branching node Ny and the base of the transistor Q2.

The circuit arrangement 1 furthermore contains a capacitor C3, one end of which is connected to a node N1 of the first signal path SP1, which node lies downstream of the level shifter in the signal flow direction, and the other end of which is connected to a node N2 of the second signal path SP2. In the present example, the node N1 is the node to which the collector of the transistor Q6 and the base of the transistor Q1 are connected, and the node N1 is the branching node Ny.

During operation, a supply voltage Vcc is applied between the supply terminal VCC and the ground terminal.

The RC element formed from the resistor R5 and the capacitor C5 serves as a low-pass filter and filters out noise interferences possibly contained on the supply voltage Vcc in order to provide a voltage on the internal supply line which is as free of interference as possible. In this case, the resistance value of the resistor is selected with a low resistance such that the voltage on the internal supply line corresponds essentially to the supply voltage Vcc.

A voltage signal Vin, which is supplied, for example, by a microcontroller and is used to switch the MOSFET M1 between a switched-on state (“on-state”) and a switched-off state (“off-state”), is applied to the input terminal IN1.

An external voltage Ve, for example with the supply voltage of 3.3 V which is customary for microcontrollers, is applied to the input terminal IN2.

In the case of a high level of the voltage signal Vin, for example with a voltage of 3.3 V which is customary for outputs of microcontrollers, a base current flows through the output transistor Q2 such that the latter becomes conductive. At the same time, the voltage level is shifted upward by the level shifter to such an extent that the output transistor Q1 blocks. As a result, the gate of the field-effect transistor M1 is pulled to ground, and the field-effect transistor M1 blocks.

In the case of a low level of the voltage signal Vin, for example with a voltage of 0 V, no base current flows through the output transistor Q2 such that the latter blocks. The voltage level shifted upward by the level shifter is now so far below the supply voltage Vcc that it brings about a base current through the output transistor Q1. As a result, the latter becomes conductive and pulls the gate of the field-effect transistor M1 to a positive voltage, as a result of which the latter becomes conductive.

The circuit arrangement 1 therefore operates as an inverting driver which outputs a high voltage in the case of a low level of the input signal and a low voltage in the case of a high level of the input signal.

As a result of the interconnection of the output transistors Q1, Q2 described above, a voltage is brought about between the output terminal OUT1 and the supply terminal VCC or between the output terminal OUT2 and the ground terminal GND, when the respective output transistor Q1 or Q2 is switched on, is very much smaller than the base-emitter voltage of 0.6 V arising in the prior art, for example approximately 0.05 V. As a result, the voltage swing of the output voltage can be increased, as a result of which in turn the rail-to-rail capability is improved.

The provision of two separate output terminals makes it possible to configure one individually as a current source and the other individually as a current sink. Thus, for example, a resistance value of the high-side output resistor R10 can be selected to be greater than a resistance value of the low-side output resistor R4, preferably greater by at least the factor 2, further preferably greater by at least the factor 4. As a result of the separate dimensioning, the rise time and the fall time of the gate voltage of the field-effect transistor M1 can also be matched to one another, as a result of which the switchover process can take place more symmetrically than in the prior art.

In order to achieve an off-state of the MOSFET M1, the low-side output transistor Q2 has to be switched on, for example by a voltage signal Vin with a high level or, if the input IN1 is not connected, internally via the resistor R3. In contrast to the prior art described above, however, in this state no collector current flows via the transistor Q6 contained in the level shifter because the latter blocks in the case of a voltage signal Vin with a high level. Compared with the prior art, the circuit arrangement 1 accordingly has a significantly reduced quiescent current.

The capacitor C3 forms a low-impedance AC current path which allows alternating components of the voltage signal Vin to pass through. In the case of a voltage jump of the voltage signal Vin, this jump is transmitted via the capacitor C3 substantially more quickly to the base of the output transistor Q1 than would take place in the case of omission of the capacitor C3 via the level shifter reacting with a certain time delay.

As a result, the switching on and off of the high-side output transistor Q1 is accelerated. However, this AC current path does not contribute to a DC current flow between VCC and GND.

In particular, the capacitor C3 is dimensioned such that, in the event of a level change of the voltage at the input terminal IN1 from the low level to the high level, a pulse current is conducted from the input terminal IN1 via the capacitor C3 directly without delay to the base of the transistor Q1, in order to switch the latter on and off without delay and very quickly in such a way that the transistor Q1 is already switched off when the transistor Q2 is completely switched on, and vice versa. As a result, an undesired transverse current between the first transistor Q1 and the second transistor Q2 is successfully prevented.

As a result of the parallel circuit of the capacitor C3 with the transistor Q6 operated in a common base circuit and with its emitter resistor R6, a very fast level shift and a fast transmission of pulse signals are therefore realized.

If the capacitor C3 were connected directly without the resistor R2 to the input terminal IN1, a very high peak current could flow through the input terminal IN1. In this case, the resistor R2 serves for the suitable current limitation of the current through the input terminal IN1, with the aim of protecting the control unit (for example the microcontroller) from an excessively high peak current. In this case, the resistor R2 is connected in series with the capacitor C3 and has a suitable resistance value, such that the peak current through the input terminal IN1 lies in the advantageous range 1 mA . . . 30 mA and particularly advantageously in the range 3 mA . . . 10 mA.

According to the present embodiment, the constant voltage which is required for the transistor Q6 in a common base circuit is generated via a voltage divider from the external voltage Ve present at the input terminal IN2. Compared with an internal generation from the supply voltage Vcc, which is likewise possible as an alternative, this solution affords further advantages. Thus, the external voltage Ve may have, for example, a voltage value which is essentially equal to a high level of the voltage signal Vin. As a result, the base voltage of the transistor always lies between the high level of the voltage signal Vin and ground. Thus, the circuit arrangement 1 can be flexibly adapted to different voltage levels of a source for the voltage signal Vin.

Alternatively, a suitable external voltage could also be applied without a voltage divider. However, the use of the voltage divider makes it possible to achieve a suitable signal-to-noise ratio with respect to interference voltages on the internal supply line WI or on the voltage signal Vin and to set it in a suitable manner.

As an example, the supply voltage of the microcontroller of 3.3 V is selected as the voltage value for the external voltage Ve in the present embodiment. Said supply voltage also corresponds essentially to the high level of a signal supplied by the microcontroller, whereas the low level lies at approximately 0 V. Alternatively, the external voltage Ve can also be supplied by an output of the microcontroller which is kept permanently at a high level.

If a logic with a high level of 5 V is later used instead of the microcontroller to generate the voltage signal Vin, the circuit arrangement can be easily adapted to the changed signal level by applying 5 V to the input terminal IN2. Furthermore, interference voltages (noise, switching spikes) possibly present on the external voltage Ve are reduced by the voltage divider.

Advantageous dimensioning is described below. In this case, a high level and a low level of the voltage signal Vin are denoted by VINmax and VINmin. Depending on the voltage value of the external voltage Ve, a ratio between the resistance values of the voltage divider resistor R21 and of the voltage divider resistor R22 is selected, for example, in such a way that the base voltage Vb present at the base of the third transistor Q6 lies in a range from

$$V IN max - 1.5 * ( V IN max + V IN min ) / 2 to V IN max or from 0.9 V to V IN max ,$$

preferably lies in a range from

$$V IN max - 0.6 * ( V IN max + V IN min ) / 2 to V IN max - 0.3 * ( V IN max + V IN min ) / 2 ,$$

The input terminal IN2 can also be used as an enable input. For example, the external voltage Ve applied to the input terminal IN2 can be set to a level of 0V during the switch-on operation (power-up) and only after a time delay to the value required for generating the desired base voltage Vb. As a result, independently of the voltage state at the input terminal VIN, it can be ensured that the field-effect transistor M1 remains reliably switched off during the entire switch-on operation and can only be switched on after the transient processes have subsided. The external voltage Ve therefore acts here as an enable signal for blocking (disable) and enabling (enable) the operation of the circuit arrangement 1.

Similarly to the capacitor C3, the capacitor C2 also forms a low-impedance AC current path which allows alternating components of the voltage signal Vin to pass through and leads past the resistor R9. In the case of a voltage jump of the voltage signal Vin, this jump is therefore also transmitted more quickly via the capacitor C2 to the base of the output transistor Q2 than without the capacitor C2. As a result, the switching on and off of the low-side output transistor Q2 is also accelerated.

A ratio between a capacitance value of the capacitor C3 and a capacitance value of the capacitor C2 is preferably selected to be between 0.25 and 4, preferably between 0.5 and 2, still further preferably between 0.75 and 1.5.

The capacitance value of the capacitor C2 and the resistance value of the resistor R9 are matched to one another such that a time constant τ=R9*C2 preferably lies in a range from 100 ns to 3000 ns, further preferably in a range from 200 ns to 1500 ns.

A switch-off voltage signal Vsd, which is supplied, for example, by an overtemperature protection circuit, can be applied to the third input terminal IN3. In the case of a high level of the switch-off voltage signal Vsd, the transistor Q2 conducts and the transistor Q1 blocks, such that the gate of the field-effect transistor M1 is pulled to ground. The input IN3 therefore acts in an inverting manner.

In this case, the switch-off voltage signal Vsd overwrites the voltage signal Vin input via the input IN1 and ensures that the field-effect transistor M1 remains permanently switched off independently of the level of the voltage signal Vin.

The diodes D1, D3 and D4 are optional, but contribute to improving the circuit arrangement 1.

The diode D1 serves to prevent a polarity reversal of the output voltage on account of the capacitive current from the drain of the MOSFET or on account of the Miller effect during the voltage drop. It has the effect that the collector of the output transistor Q2 remains at a positive potential with respect to the ground potential, since the transistor could otherwise be damaged by the breakdown of the base-emitter junction.

The diodes D3 and D4 serve to avoid saturation of the respective transistors.

Numerous modifications of the described embodiment are possible.

Thus, the circuit arrangement can be realized, for example, with inverted polarities of the transistors and of the voltages.

The output resistors R10 and R4 can be arranged between the collectors of the corresponding output transistors Q1, Q2 and the corresponding output terminals OUT1, OUT2 instead of between the output terminals OUT1, OUT2 and the gate of the MOSFET M1. Each output resistor can also be divided between an internal partial resistor (located between the output transistor and the output terminal) and an external partial resistor (located between the output terminal and the MOSFET).

Instead of the two output terminals OUT1, OUT2, a common output terminal can be provided, to which the collectors of the two transistors Q1, Q2 are connected directly or in each case via a resistor. As a result of corresponding dimensioning of the internal and external output resistors, even in the case of a common output terminal, the functions as a current source and as a current sink can be configured individually in a similar way, as described above for the separate output terminals and the external output resistors.

The emitter of the transistor Q6 can be connected directly or via its emitter resistor R6 to the input terminal IN1. In this case, the two signal paths SP1, SP2 do not have a common partial path, and the branching node Ny is the input terminal IN1.

The circuit arrangement may contain a further PNP bipolar transistor which is connected to the NPN bipolar transistor Q2 in the form of a complementary Darlington circuit. This complementary Darlington circuit then acts as an NPN bipolar transistor with increased current gain.

The level shifter may also be realized by another known level shift circuit instead of by a bipolar transistor in a common base circuit.

The transistor Q2 may also be configured as an N-channel field-effect transistor instead of as a bipolar transistor, for example as an N-MOSFET. In this embodiment variant, the diodes D1 and D4 may be omitted. D1 is intrinsically present in the N-MOSFET. D4 as an anti-saturation diode is not necessary in the case of a transistor Q2 configured as in the N-MOSFET.

### LIST OF REFERENCE NUMERALS

circuit arrangement, switching assembly 1, 100
capacitor C
diode D
ground terminal GND
input terminal IN
MOSFET M
node N
branching node Ny
output terminal OUT
transistor Q
output transistor Q1, Q2
resistor R
external output resistor R4, R10
supply resistor R5
emitter resistor R6
external load R7, R100
voltage divider resistor R21, R22
signal path SP
base voltage Vb
supply terminal VCC
supply voltage Vcc
external voltage or enable signal Ve
DC voltage Vdc
voltage signal Vin
output voltage Vout
switch-off voltage signal Vsd
internal supply line WI

1. A circuit arrangement for driving a load, the circuit arrangement comprising:
a ground terminal and a supply terminal for applying a supply voltage,
a first input terminal for inputting a voltage signal in order to switch between states of the load,
a first and a second output terminal for respectively outputting a first and second output voltage for driving the load, or a common output terminal for outputting a common output voltage for driving the load,
a first transistor and a second transistor, (i) wherein the first transistor is formed as a PNP bipolar transistor and the second transistor is formed as an NPN bipolar transistor or as an N-channel field-effect transistor or (ii) wherein the first transistor is formed as an NPN bipolar transistor and the second transistor is formed as a PNP bipolar transistor or as a P-channel field-effect transistor,
a first signal path which is connected directly or via a first resistor between the first input terminal and a base of the first transistor, and
a second signal path which is connected directly or via the first resistor between the first input terminal and a base or a gate of the second transistor, wherein
an emitter of the first transistor is connected directly or via a supply resistor to the supply terminal,
a collector of the first transistor is connected directly or via a first internal output resistor to the first output terminal or to the common output terminal,
an emitter or a source of the second transistor is connected directly or via an emitter resistor to the ground terminal,
the collector or a drain of the second transistor is connected directly or via a second internal output resistor to the second output terminal or to the common output terminal,
the first signal path contains a level shifter which is configured to shift the voltage signal into a level range suitable for switching the first transistor, and
the first signal path furthermore contains a first capacitor, one end of which is connected directly or via the first resistor to the first input terminal and the other end of which is connected directly or via a second resistor to the base of the first transistor.

2. The circuit arrangement according to claim 1, which is dimensioned such that, in the event of a level change of the voltage signal at the first input terminal, a pulse current from the first input terminal is conducted via the first capacitor to the base of the first transistor so quickly that the first transistor is already switched off when the second transistor is completely switched on, and vice versa.

3. The circuit arrangement according to claim 1, wherein
the second signal path contains a parallel circuit comprising a second capacitor and a third resistor, wherein the parallel circuit is connected in series with the base or the gate of the second transistor.

4. The circuit arrangement according to claim 3, wherein
a ratio between a capacitance value of the first capacitor and a capacitance value of the second capacitor lies in a range from 0.25 to 4.

5. The circuit arrangement according to claim 3, wherein
a time constant, which results as a product of a resistance value of the third resistor and a capacitance value of the second capacitor, lies in a range from 100 ns to 3000 ns.

6. The circuit arrangement according to claim 1, wherein
the level shifter contains a third transistor which is formed as a bipolar transistor of the same polarity as the second transistor and is connected in a common base circuit.

7. The circuit arrangement according to claim 6, furthermore containing
a second input terminal for inputting an external voltage or an enable signal, and
wherein the second input terminal is connected directly or via a voltage divider to a base of the third transistor.

8. The circuit arrangement according to claim 7, wherein
the second input terminal is connected via a first voltage divider resistor to the base of the third transistor, and
the base of the third transistor is connected via a second voltage divider resistor to the ground terminal.

9. The circuit arrangement according to claim 1, wherein
the first and the second signal path are configured such that, when the voltage signal having a low level is input at the first input terminal, an output voltage at the first output terminal or the common output terminal is substantially equal to the supply voltage, whereas, when the voltage signal having a high level is input at the first input terminal, an output voltage at the first output terminal or the common output terminal is substantially equal to ground potential.

10. The circuit arrangement according to claim 1, furthermore containing a third input terminal for inputting a switch-off voltage signal,
wherein the first signal path and the second signal path are connected via the first resistor to the first input terminal and
the third input terminal is connected to a node which is common to the first and the second signal path but is not the first input terminal.

11. The circuit arrangement according to claim 1, wherein the first transistor is formed as a PNP bipolar transistor and the second transistor is formed as an NPN bipolar transistor and the circuit arrangement furthermore includes a group consisting of:
a first diode which is connected on an anode side to the emitter and on a cathode side to the collector of the second transistor,
a second diode which is connected on an anode side to the collector and on a cathode side to the base of the first transistor,
a third diode which is connected on an anode side to the base and on a cathode side to the collector of the second transistor, and
combinations thereof.

12. The circuit arrangement according to claim 1, wherein
the second transistor is formed by a complementary Darlington circuit comprising a fourth transistor of a polarity of the second transistor and a fifth transistor of a polarity of the first transistor.

13. The circuit arrangement according to claim 1, furthermore comprising a power transistor having a gate,
wherein the gate of the power transistor is connected directly or via a first external output resistor to the first output terminal and directly or via a second external resistor to the second output terminal, or
wherein the gate of the power transistor is connected directly or via an external output resistor to the common output terminal.

14. A circuit arrangement according to claim 13, wherein a first total sum of resistances between the collector of the first transistor and the gate of the power transistor is greater than a second total sum of resistances between the collector or the drain of the second transistor and the gate of the power transistor.

15. The circuit arrangement according to claim 4, wherein
the ratio between the capacitance value of the first capacitor and the capacitance value of the second capacitor lies in a range from 0.5 to 2.

16. The circuit arrangement according to claim 5, wherein
the time constant, which results as the product of the resistance value of the third resistor and the capacitance value of the second capacitor, lies in a range from 200 ns to 1500 ns.

17. The circuit arrangement according to claim 6, wherein
the level shifter furthermore contains a first resistor which is connected in series with the emitter of the third transistor.

18. The circuit arrangement according to claim 7, wherein
the second input terminal is designed for use as an enable input for blocking or enabling operation of the first transistor.

19. The circuit arrangement according to claim 8, wherein
a ratio between resistance values of the first voltage divider resistor and of the second voltage divider resistor is selected in such a way that a base voltage present at the base of the third transistor lies in a range from
VINmax−1.5(VINmax+VINmin)/2 to VINmax or from 0.9V to VINmax,
wherein VINmax corresponds to a high level and VINmin corresponds to a low level of the voltage signal.

20. The circuit arrangement according to claim 14, wherein
wherein the first total sum of the resistances between the collector of the first transistor and the gate of the power transistor is greater than the second total sum of the resistances between the collector or the drain of the second transistor and the gate of the power transistor by at least a factor of 2.
